(19) United States
(12) Patent Application Publication
(10) Pub. No.: US 2024/0379466 A1
(43) Pub. Date: Nov. 14, 2024

(54) Method for Providing Wafer Test Data of at Least One Wafer with Semiconductor Chips

(71) Applicant: Robert Bosch GmbH, Stuttgart (DE)

(72) Inventors: Timo Pfrommer, Stuttgart (DE); Anton Iakovlev, Boeblingen (DE); Damir Shakirov, Niefern-Oeschelbronn (DE); David Schoenleber, Karlsruhe (DE); Joseph Trotta, Stuttgart (DE); Keng Chai, Stuttgart (DE); Mehul Bansal, Sindelfingen (DE)

(21) Appl. No.: 18/659,719

(22) Filed: May 9, 2024

(30) Foreign Application Priority Data
May 11, 2023 (DE) 10 2023 204 387.4

(51) Int. Cl. H01L 21/66; G06N 20/10

(52) U.S. Cl. CPC H01L 22/20; G06N 20/10; H01L 22/12

(57) ABSTRACT

A method for providing wafer test data of at least one wafer with semiconductor chips, in particular for providing a training data set for a machine learning algorithm for anomaly detection, comprising receiving a set of measured variables from the semiconductor chips of the wafer, defining sub-areas on the wafer, each of which comprises a plurality of semiconductor chips of the wafer for which measured variables have been received, and outputting a reduced set of measured variables compared to the received set of measured variables, which comprises only the measured variables of subsets of the semiconductor chips of the respective sub-areas.

This application claims priority under 35 U.S.C. § 119 to application no. DE 10 2023 204 387.4, filed on Nov. 5, 2023 in Germany, the disclosure of which is incorporated herein by reference in its entirety.

The disclosure relates to methods for providing wafer test data of at least one wafer with semiconductor chips. The disclosure also relates to a method for teaching a machine learning algorithm. Furthermore, the disclosure relates to a system, a computer program with program code and a computer-readable storage medium for executing at least one of said methods.

### BACKGROUND

Methods for reducing a data set have already been proposed, wherein the data is grouped, for example by country, and then the data within each group is randomly removed.

Furthermore, a method for reducing a three-dimensional data set has already been proposed, wherein the data is projected into sub-areas and a data point is selected for each sub-area.

However, both methods do not take into account the measurement properties of the semiconductor chips on a wafer and are therefore not applicable to measurement data from wafer tests.

### SUMMARY

A method for providing wafer test data of at least one wafer with semiconductor chips, in particular for providing a training data set for a machine learning algorithm for anomaly detection, is proposed, comprising at least the following steps:
Receiving a set of measured variables of the semiconductor chips of the wafer, preferably by means of a measured variable transmission to a computing device, preferably a processor of the computing device, in particular from a storage medium of the computing device and/or from a measuring device,
Defining sub-areas on the wafer, preferably with the computing device, particularly preferably with the processor of the computing device, each of which comprises a plurality of semiconductor chips of the wafer for which measured variables have been received,
Outputting a reduced set of measured variables compared to the received set of measured variables, preferably to the storage medium of the computing device, particularly preferably to the machine learning algorithm as a training data set, which only comprises the measured variables of subsets of the semiconductor chips of the respective sub-areas.

The method according to the disclosure can advantageously reduce the wafer test data for the training data set for the machine learning algorithm. Furthermore, the output of a reduced set of measured variables, in particular a resulting training data set, can advantageously increase the speed of data processing, in particular when teaching the algorithm, in particular while maintaining the quality of the training data set, and/or more cost-effective processors can be used, in particular since semiconductor chips arranged next to each other on a wafer have at least in part, in particular for the most part, insignificant differences in the measured variables. Furthermore, by defining sub-areas on the wafer, it can be advantageously ensured that all areas of the wafer are at least partially considered equally. Since anomalies that occur due to the production of the wafer usually occur over a large number of semiconductor chips, especially adjacent ones, the anomaly can be detected advantageously even with a reduced set of measured variables, especially in defined sub-areas. Furthermore, the method is particularly easy to use.

In particular, the method provides a reduced data set of wafer test data, especially with regard to a number of wafer test data, preferably with regard to a number of measured variables compared to the measured variables of the semiconductor chips. In particular, the wafer test data shows the measured variables of the semiconductor chips. The wafer test data are measured variables of semiconductor chips, which are arranged at least on the wafer, preferably on a plurality of wafers. Preferably, the wafer, in particular the semiconductor chips on the wafer, is completely manufactured when the measured variables are measured. In particular, this means that all layers of the wafer are produced when the measured variables are measured and, in particular, that the semiconductor chips on the wafer are fully connected to the wiring on the wafer. Preferably, the wafer test data are wafer-level test data, which in particular have the measured variables of the fully manufactured semiconductor chips, especially after a manufacturing process of the wafer. In particular, the wafer-level test data is recorded to ensure that the semiconductor chips on the wafer function according to the defined requirements of the semiconductor chips.

The method is used to provide a training data set for a machine learning algorithm intended for anomaly detection. A machine learning algorithm can be understood as a model that converts inputs into specific outputs, for example through classification and/or regression. Examples of possible machine learning algorithms are artificial neural networks, genetic algorithms, support vector machines, k-means, kernel regression or discriminant analysis. The machine learning algorithm can also comprise a combination of several of the examples mentioned. The algorithm trained, in particular with the wafer test data, is particularly preferred for detecting anomalies on a wafer, in particular different wafers to the wafer of the wafer test data.

Preferably, the machine learning algorithm for anomaly detection is used to identify unusual or deviating patterns in the measured variables. In particular, the algorithm is designed to detect potential problems, faults, defects and/or other anomalies in the semiconductor chips at an early stage. This allows manufacturers to ensure the quality of the chips, increase production yield and/or improve the efficiency of the manufacturing process. Preferably, the training data set for the machine learning algorithm is a collection of structured data, in particular a collection of the measured variables used to train the algorithm. Preferably, a training data set comprises input and output variables that help the algorithm to recognize patterns and correlations in the measured variables, in particular to make predictions or decisions based on new, unknown data, in particular measured variables of new semiconductor chips on a preferably new wafer. In particular, the input quantities of the training data set are the measured quantities of the semiconductor chips and the output quantities are an anomaly score, which is preferably a quantitative value reflecting a strength of a deviation from a norm.

The wafer test data is received from a plurality of wafers with semiconductor chips on them. The wafer test data is received from a plurality of semiconductor chips. A “plurality of semiconductor chips” are at least two semiconductor chips, advantageously at least 100 semiconductor chips, preferably at least 1,000 semiconductor chips, particularly preferably at least 10,000 semiconductor chips. In particular, the semiconductor chips are arranged on at least one wafer, preferably on a plurality of wafers, advantageously on at least two, preferably on at least ten, particularly preferably on at least 100 wafers. Preferably, the wafer test data is from at least one batch of wafers, in particular semiconductor chips. A batch is preferably wafers, in particular semiconductor chips, from a transportation process from a manufacturer of the wafers and/or the semiconductor chips and/or from a manufacturer of the wafers and/or the semiconductor chips and/or a type of the semiconductor chips, in particular a design and/or structure of the semiconductor chips.

Preferably, at least the set of measured variables is measured for the wafer with the semiconductor chips, which in particular comprises the measured variables of a majority of the semiconductor chips, preferably all semiconductor chips, on the wafer. In particular, each set of measured variables has a plurality of measured variables. A plurality of measured variables are at least two, advantageously at least 100, preferably at least 1,000, and particularly preferably at least 10,000 measured variables in a set of measured variables. The set of measured variables is divided into sets of measured variables for the respective semiconductor chips on the wafer. The measured variable set of a semiconductor chip contains all the measured variables of a semiconductor chip.

The measured variables of the semiconductor chips are particularly preferably electrical measured variables. In particular, each measured variable is from a measurement of the semiconductor chip. Preferably, the measured variables are recorded with a measuring system. Preferably, the measured variables of the semiconductor chips are measured with electrical tests, wherein in particular the electrical properties and/or power of the semiconductor chip is determined. In particular, parametric measurements are performed as electrical tests, wherein the electrical properties of the semiconductor chip, in particular the voltage, the current, the capacitance and/or the resistance, preferably under different operating conditions, are measured, and/or functional measurements are performed, wherein the function of the semiconductor chips, preferably under different operating conditions, is measured electrically, and/or reliability measurements are performed, wherein the semiconductor chips are measured over a defined period of time, in particular under different operating conditions.

Alternatively or additionally, the measured variables of the semiconductor chips are measured by optical and/or acoustic tests, wherein in particular the external properties and/or the integrity of the semiconductor chips on the wafer and/or the external properties and/or the integrity of the wafer are recorded. In particular, the measured variables of the optical and/or acoustic tests are measurements of the surface, the structure and/or the dimensions of the semiconductor chips and/or the detection of cracks and/or fractures of the semiconductor chips and/or the wafer.

Preferably, the method for providing the wafer test data is carried out by a computing device. It is particularly preferable for the machine learning algorithm to be taught by the computing device. The term “computing device” refers in particular to a device with information input, information processing and information output. Advantageously, the computing device has at least one processor, a storage medium, an input and output means, further electrical components, an operating program, control routines, control routines and/or calculation routines. Particularly preferably, the storage medium of the computing device comprises a computer program with program code for carrying out the method for providing the wafer test data. In particular, the processor is preferably used to carry out the method for providing the wafer test data, especially the computer program with program code. Preferably, the components of the computing device are arranged on a common circuit board and/or advantageously arranged in a common housing. Alternatively, however, the computing device can also be designed as a distributed, in particular virtual, computing device, such as a cloud.

Preferably, the measured quantities of the semiconductor chips are received as a set of measured quantities for providing the wafer test data, in particular for providing the training data set for the machine learning algorithm. In particular, the set of measured variables is received for a reduction of the measured variables. Preferably, the set of measured variables is received by the processor of the computing device, in particular by the storage medium of the computing device. In particular, the received set of measured variables includes the measured variables of all semiconductor chips on the at least one wafer. Preferably, the measured variables of the semiconductor chips are stored on the storage medium of the computing device by the measuring system for receiving the set of measured variables, in particular for providing the wafer test data with the processor.

In particular, the wafer with the semiconductor chips is subdivided into the sub-areas when defining the sub-areas by defining, in particular projecting, sub-area boundaries onto the wafer. In particular, at least two, preferably at least three, advantageously at least five, particularly preferably at least nine sub-areas are defined on the wafer. In particular, the shape or geometry of the sub-areas can be freely defined, especially by a user. Particularly preferably, the sub-areas, especially on each wafer, preferably of a batch, preferably for each wafer for providing the wafer test data, are defined identically. Preferably, the defined sub-areas are at least partially grid-shaped, wherein preferably each sub-area is at least partially at least approximately square, in particular with horizontal and vertical sub-area boundaries. In particular, the sub-areas, in particular on each wafer, preferably of a batch, preferably for each wafer for providing the wafer test data, have a fixed number of semiconductor chips, in particular the same number for each sub-area. Preferably, the sub-areas on the wafer have at least approximately the same shape and/or have at least approximately the same surface area on the wafer.

In particular, the semiconductor chips are assigned to each sub-area. In particular, each sub-area comprises all semiconductor chips, in particular all measured variables of the semiconductor chips, within the sub-area boundaries. The term “sub-areas comprising a plurality of semiconductor chips” should be understood to mean in particular at least two, preferably at least ten, particularly preferably at least 100 semiconductor chips. In particular, the number of semiconductor chips in each sub-area is at least approximately the same.

In particular, when defining the sub-areas, the received set of measured variables of the semiconductor chips is divided into the sub-areas, in particular projected. The measured variables of the semiconductor chips are particularly preferably projected into the sub-areas, especially for the assignment of the semiconductor chips to the sub-areas. Particularly preferably, the semiconductor chips are subdivided into the sub-areas using the received set of measured variables, in particular by projecting the measured variables into the sub-areas. Preferably, the measured variables of the semiconductor chips are assigned position data, in particular x-coordinates and y-coordinates, on the wafer, by means of which the measured variables of the semiconductor chips are preferably projected into the sub-areas. In particular, the measured variables are assigned to the sub-areas by comparing the position data of the semiconductor chips with the sub-area boundaries.

Preferably, the received set of measured variables is reduced, in particular by selecting the measured variables of a subset of semiconductor chips of the respective sub-areas. In particular, a subset of all semiconductor chips of the respective sub-area is selected in each sub-area. The subset of the semiconductor chips, in particular the resulting subset of measured variables of the semiconductor chips, is in particular at most 80%, advantageously at most 50%, preferably at most 20%, particularly preferably at most 10% of the semiconductor chips, in particular of the measured variables of the semiconductor chips, in the sub-area. Preferably, the reduced set of measured variables for the subset of semiconductor chips in the sub-areas has completely available measured variables, in particular completely available sets of measured variables.

Preferably, the wafer test data is output to the storage medium of the computing device. In particular, the wafer test data for the application is output, in particular provided, as a training data set, in particular on the storage medium. In particular, the reduced, in particular output, set of measured variables compared to the received set of measured variables has in particular at most 80%, advantageously at most 50%, preferably at most 20%, particularly preferably at most 10% of the measured variables.

Furthermore, it is proposed that the semiconductor chips of the respective sub-areas, whose measured variables are assigned to the reduced set of measured variables, are determined at least partially at random. By randomly determining the semiconductor chips in the sub-areas, it can be advantageously ensured that no area of the wafer, in particular no defined sub-area, is randomly excluded. Furthermore, it is advantageous to ensure that local, in particular cross-wafer, problems are detected when randomly determining the semiconductor chips from the plurality of wafers, in particular with identically defined sub-areas.

In particular, the subset of semiconductor chips, especially the measured variables of the semiconductor chips, is determined randomly in each sub-area on the wafer. In particular, the subset of semiconductor chips, especially the measured variables of the subset of semiconductor chips, is different in each sub-area on the wafer. Preferably, a number or a proportion of the semiconductor chips, in particular the measured variables of the semiconductor chips, is at least approximately the same in the respective sub-areas. Preferably, the position data of the projected measured variables of the semiconductor chips in the received set of measured variables is used to randomly determine the subset of semiconductor chips in the respective sub-areas.

Alternatively, the position data of the semiconductor chips, in particular of the measured variables of the semiconductor chips, in particular relative to the sub-area boundaries, are determined randomly for each sub-area, wherein the same semiconductor chips are determined in the respective sub-areas on the wafer, in particular with regard to a position of the semiconductor chips, preferably relative to the sub-area boundaries. In particular, the position data of the semiconductor chips in the sub-areas is determined randomly for each additional wafer, which in particular is part of the received set of measured variables. Particularly preferably, the subset of semiconductor chips, in particular the position of the subset of semiconductor chips, in each sub-area on the wafer is different for each wafer, which is in particular part of the received set of measured variables. Preferably, the output set of measured variables only contains measured variables from randomly determined semiconductor chips in the respective sub-areas of the wafer.

It is also proposed that the semiconductor chips of the respective sub-areas, whose measured variables are assigned to the reduced set of measured variables, are determined at least partially according to a predetermined pattern. This makes it possible to achieve an optimal selection of measured variables for the creation of the training data set. Furthermore, it can be advantageously ensured that the measured variables from neighboring semiconductor chips are sorted out when the set of measured variables is reduced.

In particular, a pattern is specified, in particular defined, for the sub-areas of the wafer, on the basis of which the subset of semiconductor chips, in particular of measured variables of the semiconductor chips, is determined. In particular, a number and/or a position of the semiconductor chips, in particular for the subset of semiconductor chips for the subset of measured variables, is determined in the sub-areas as a predetermined pattern. Particularly preferably, at least one semiconductor chip, in particular the measured variables of at least one semiconductor chip, is determined in each sub-area as a predefined pattern. Preferably, the semiconductor chips, in particular for the reduced set of measured variables, are determined across sub-areas using the pattern according to a fixed interval.

Furthermore, it is proposed that the sub-areas are defined on the basis of properties of the wafer and/or on the basis of photomask positions and/or exposure schemes from the manufacturing process of the wafer. As a result, the subset of semiconductor chips, in particular a proportion of the semiconductor chips in each sub-area, can be advantageously adapted to the production-related properties of the wafer, in particular the associated qualitative differences of the wafer, in particular the semiconductor chips on the wafer.

In particular, a number of semiconductor chips of the specific subset of semiconductor chips in the defined sub-areas is dependent on the properties of the wafer or, in particular in the case of a fixed number of semiconductor chips in the respective sub-areas, a size of the defined sub-areas is dependent on the properties of the wafer. The properties of the wafer are in particular technical and/or production-related and/or transport-related properties of the wafer, which in particular have an influence on the quality of the semiconductor chips in various sub-areas of the wafer. In particular, the quality of the semiconductor chips is dependent on radial concentricity, especially due to production and/or transportation. Preferably, when defining the sub-areas on the basis of photomask positions and/or exposure schemes, the sub-area boundaries are defined by controlling or moving a photomask during the manufacturing process. In particular, the sub-areas, preferably the sub-area boundaries, can at least partially correspond to photomask positions and/or exposure schemes from the wafer manufacturing process. It is particularly preferable to define the sub-area boundaries using the edges of the moving photomask.

Preferably, the defined sub-areas are at least partially circular, in particular based on the properties of the wafer, wherein the circular sub-areas preferably are arranged concentrically, wherein each sub-area, in particular as a concentric ring, has a uniform distance from the center of the wafer. Preferably, more semiconductor chips are determined in a concentric outer sub-area of the wafer than in a concentric inner sub-area of the wafer as a subset of the semiconductor chips, in particular for quality reasons. In particular, a property-related difference between the number of semiconductor chips in the sub-areas is within a range of in particular at most 40%, advantageously at most 20%, preferably at most 10%, particularly preferably at most 5%. Alternatively or additionally, properties of the wafer are a shape of the wafer, a size of the wafer, a division of the wafer and/or an orientation of the semiconductor chips on the wafer.

Furthermore, it is proposed that a probability distribution for the presence of an anomaly on the wafer is determined and the sub-areas on the wafer are defined depending on the determined probability distribution. This allows semiconductor chips with a higher probability of an anomaly to be included in the reduced set of measured variables with a higher probability. It is also advantageous to ensure that most of the semiconductor chips for the subset are taken in sub-areas with a high probability of anomalies, so that known problems are easily detected. Furthermore, the measured variables of semiconductor chips can be used to detect new problematic areas of the wafer from sub-areas that have a low probability of anomalies, especially those that develop over time.

In particular, the defined sub-areas each have at least approximately the same probability of the presence of an anomaly. Preferably, the sub-area boundaries are defined by a probability value for the presence of an anomaly on the wafer. Preferably, the probability distribution for the presence of an anomaly on the wafer is learned, in particular using a machine learning model. A machine learning model can be understood as a model that converts inputs into specific outputs, for example through classification and/or regression. Examples of possible machine learning models are artificial neural networks, genetic algorithms, support vector machines, k-means, kernel regression or discriminant analysis. Preferably, in the sub-areas in which the probability of the presence of an anomaly on the wafer is higher, in particular in comparison with the other sub-areas, a larger number of semiconductor chips, in particular in comparison with the other sub-areas, is determined as a subset of the semiconductor chips, in particular for the reduced set of measured variables. In particular, more semiconductor chips are determined for the subset of chips in a sub-area with a higher probability of the presence of an anomaly than in a sub-area with a lower probability. In particular, the sub-areas on the wafer are defined as sub-area boundaries using probability lines. Preferably, the probability lines are defined by threshold values of the probability distribution, in particular those defined by a user. In particular, the probability lines comprise sub-areas with at least approximately the same probability for the presence of an anomaly on the wafer. In particular, a size of the sub-areas depends on the probability of the presence of an anomaly in the sub-area, in particular depending on the defined threshold value of the probability distribution.

Furthermore, a method for providing wafer test data of at least one wafer with a plurality of semiconductor chips, in particular for providing a training data set for a machine learning algorithm for anomaly detection, comprising at least the following steps:
defining sub-areas on the wafer, preferably by a computing device of a measuring system, each of which comprises a plurality of semiconductor chips of the wafer,
measuring, preferably with a measuring device of the measuring system, of only a subset of the semiconductor chips in the respective sub-areas, which is particularly preferably determined by the computing device of the measuring system, and
outputting, preferably with the computing device of the measuring system, a set of measured variables, preferably to a storage medium of the computing device, particularly preferably to the machine learning algorithm, especially as a training data set.

The method according to the disclosure can advantageously reduce a time when measuring a wafer, in particular for testing the quality of the semiconductor chips on the wafer, in particular with regard to the presence of an anomaly. Furthermore, the measurement costs for each wafer, in particular for a batch of wafers, can be advantageously reduced, preferably for very costly measurements. In addition, the wafer test data for the training data set for the machine learning algorithm can be advantageously reduced. Furthermore, the output of a reduced set of measured variables, in particular resulting from a reduced number of measurements of semiconductor chips, in particular a resulting training data set, can advantageously increase the speed of data processing, in particular when teaching the algorithm, in particular while maintaining the quality of the training data set, and/or more cost-effective processors can be used, in particular since semiconductor chips arranged next to each other on a wafer have at least in part, in particular for the most part, insignificant differences in the measured variables. Furthermore, by defining sub-areas on the wafer, it can be advantageously ensured that all areas of the wafer are at least partially considered equally.

Preferably, the semiconductor chips to be measured are reduced. In particular, the sub-areas are defined in accordance with the above method. Preferably, the position data of the individual semiconductor chips are projected into the sub-areas. Preferably, the subset of semiconductor chips is determined according to the method described above, in particular randomly or according to a pattern.

Preferably, the method is at least partially executed by the measurement system for providing wafer test data on a wafer with a plurality of semiconductor chips. Particularly preferably, the measuring system has a measuring device that measures at least a subset of the semiconductor chips in at least one defined sub-area on the wafer. Preferably, the measuring system has a computing device which is configured to define the sub-areas on the wafer and to determine the subset of semiconductor chips in at least one of the sub-areas.

Further, a method for training the machine learning algorithm for anomaly detection with a training data set provided at least partially with one of the methods for providing the wafer test data is proposed. With the reduced training data set, the method according to the disclosure can advantageously accelerate the teaching of the algorithm, in particular while maintaining the performance of the taught algorithm.

Furthermore, a system for providing the wafer test data and/or for teaching the machine learning algorithm is proposed, comprising the computing device which is configured to execute at least one of the above-mentioned methods. The system according to the disclosure can advantageously reduce the wafer test data for the training data set for the machine learning algorithm. Furthermore, the output of a reduced set of measured variables, in particular a resulting training data set, can advantageously increase the speed of data processing, in particular when teaching the algorithm, in particular while maintaining the quality of the training data set, and/or more cost-effective processors can be used, in particular since semiconductor chips arranged next to each other on a wafer have at least in part, in particular for the most part, insignificant differences in the measured variables. Furthermore, by defining sub-areas on the wafer, it can be advantageously ensured that all areas of the wafer are at least partially considered equally.

Furthermore, a computer program with program code is proposed, comprising instructions which, when the program code is executed by a computer, cause the computer to execute at least one of the above-mentioned methods. The computer program with program code according to the disclosure can advantageously reduce the wafer test data for the training data set for the machine learning algorithm. Furthermore, the output of a reduced set of measured variables, in particular a resulting training data set, can advantageously increase the speed of data processing, in particular when teaching the algorithm, in particular while maintaining the quality of the training data set, and/or more cost-effective processors can be used, in particular since semiconductor chips arranged next to each other on a wafer have at least in part, in particular for the most part, insignificant differences in the measured variables. Furthermore, by defining sub-areas on the wafer, it can be advantageously ensured that all areas of the wafer are at least partially considered equally.

Furthermore, a computer-readable storage medium is proposed on which the computer program with program code is stored.

The methods according to the disclosure, the system according to the disclosure, the computer program according to the disclosure and the computer-readable storage medium are not intended to be limited to the application and embodiment described above. In particular, the methods according to the disclosure, the system according to the disclosure, the computer program according to the disclosure and the computer-readable storage medium can have a number of individual elements, components and units as well as method steps that differs from a number mentioned herein in order to fulfill a mode of operation described herein. Moreover, regarding the ranges of values indicated in this disclosure, values lying within the boundaries specified hereinabove are also intended to be considered as disclosed and usable as desired.

### BRIEF DESCRIPTION OF THE DRAWINGS

Further advantages follow from the description of the drawings hereinafter. Two exemplary embodiments of the disclosure are shown in the drawings. The drawings, the description, and the claims contain numerous features in combination. A person skilled in the art will appropriately also consider the features individually and combine them into additional advantageous combinations.

### Shown are:

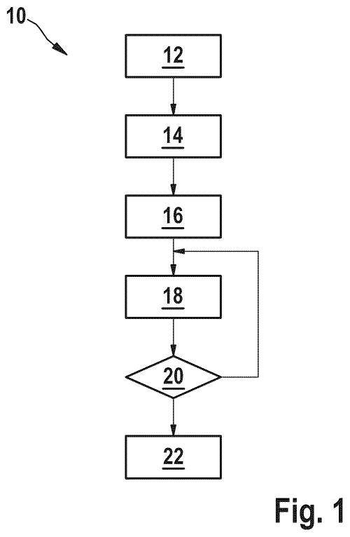

FIG. 1 a flowchart of a method according to the disclosure for providing wafer test data,

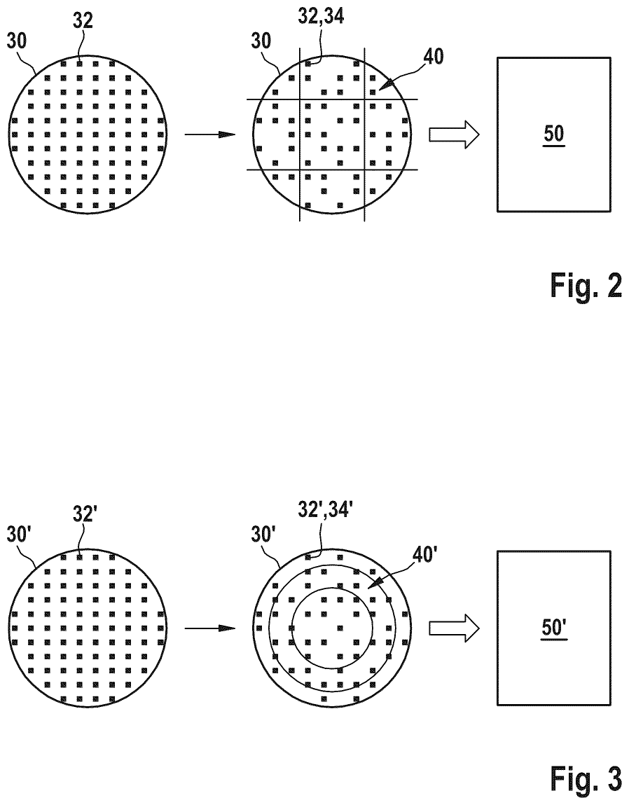

FIG. 2 a schematic representation of a wafer with semiconductor chips in grid-like sub-areas and a system for providing wafer test data,

FIG. 3 a schematic representation of a wafer with semiconductor chips in concentric sub-areas and a system for providing wafer test data and

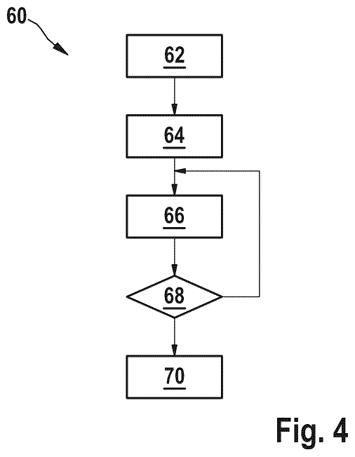

FIG. 4 a flowchart of another method for providing wafer test data.

### DETAILED DESCRIPTION

FIG. 1 shows a flowchart of a method 10 for providing wafer test data. The method 10 is intended to provide the wafer test data of at least one wafer 30 with measured variables of semiconductor chips 32 (see FIG. 2). The method 10 is provided for providing the wafer test data of the plurality of semiconductor chips 32 for a training data set for a machine learning algorithm provided for anomaly detection.

The method 10 according to the disclosure provides a reduced wafer test data set. The wafer test data consists of at least one set of measured variables. Method 10 reduces the set of measured variables. The set of measured variables includes measured variables of the semiconductor chips 32. The set of measured variables comprises the measured variables of the semiconductor chips 32 on at least one wafer 30. Measured variables are available for each semiconductor chip 32. The semiconductor chips 32 are arranged on at least one wafer 30. A plurality of measured variables are recorded for each semiconductor chip 32. Several hundred measured variables are recorded for each semiconductor chip 32. The measured variables are electrical measured variables. The measured variables are measured with electrical tests of the semiconductor chips 32. The measured variables are measured by the semiconductor chips 32 on the wafer 30. A set of measured variables is measured for each semiconductor chip 32. The set of measured variables contains the measured variables of the respective semiconductor chips 32. All sets of measured variables of the semiconductor chips 32 on all wafers form the set of measured variables.

In at least one method step 12, the set of measured variables is received. The set of measured variables of the semiconductor chips 32 of the at least one wafer 30 is received. The set of measured variables is received to provide the wafer test data. The measured variables of the semiconductor chips 32 are received as a set of measured variables. The received set of measured variables comprises the measured variables of the semiconductor chips 32 on the at least one wafer 30. The received set of measured variables includes all measured variables of all semiconductor chips 32 on the at least one wafer 30.

In at least one further method step 14, sub-areas 40 are defined on the wafer 30. The sub-areas 40 each comprise a plurality of semiconductor chips 32 of the wafer 30, for which measured variables were received. The wafer 30 with the semiconductor chips 32 is divided into the sub-areas 40 by defining sub-area boundaries on the wafer 30. The sub-area boundaries comprise the sub-areas 40 on the wafer. The sub-area boundaries are projected onto the wafer 30. Each sub-area 40 comprises all semiconductor chips 32 within the sub-area boundaries. The received set of measured variables comprises all measured variables of the semiconductor chips 32 of the defined sub-areas 40. A plurality of sub-areas 40 are defined on the wafer 30. In the case of a plurality of wafers, the sub-areas 40 are defined identically on each wafer 30.

In at least one embodiment of the method 10 according to the disclosure, the wafer 30 is subdivided into sub-areas 40 of at least approximately equal size. Each sub-area 40 has at least approximately the same number of semiconductor chips 32 (see FIG. 2).

In an alternative embodiment of the method 10 according to the disclosure, the sub-areas 40 are defined on the basis of properties of the wafer 30. The properties of the wafer 30 are technical and/or transport-related properties of the wafer 30. The properties have an influence on the quality of the semiconductor chips 32 in the various sub-areas 40 of the wafer 30 (see FIG. 3). Thus, the number of semiconductor chips 32 in the subset for the reduced set of measurands can be adapted to the quality of the semiconductor chips 32 in the various sub-areas 40.

In a further alternative embodiment of the method 10 according to the disclosure, the sub-areas 40 are defined on the basis of manufacturing-based properties of the wafer 30. The sub-areas 40 are defined on the basis of photomask positions from the manufacturing process of the wafer 30. The sub-areas 40 are defined on the basis of exposure schemes from the manufacturing process of the wafer 30. When defining the sub-areas 40 on the basis of photomask positions and/or exposure schemes, the sub-area boundaries are defined by controlling or moving a photomask during the manufacturing process.

In a further alternative embodiment of the method 10 according to the disclosure, a probability distribution for the presence of an anomaly on the wafer 30 is determined. The sub-areas 40 on the wafer 30 are defined depending on the determined probability distribution. The probability distribution is trained for the presence of an anomaly on wafer 30 using a machine learning model. In the sub-areas 40 in which the probability of the presence of an anomaly on the wafer is higher compared to the other sub-areas 40, a larger number of semiconductor chips 32 is determined as a subset of the semiconductor chips 32 compared to the other sub-areas 40.

In at least one further method step 16, the set of measured variables is projected into the sub-areas 40. The semiconductor chips 32 are assigned to each sub-area 40. When defining the sub-areas 40, the received set of measured variables of the semiconductor chips 32 is projected into the sub-areas 40. The measured variables of the semiconductor chips 32 are projected into the sub-areas 40. The measured variables of the semiconductor chips 32 are projected into the sub-areas 40 for the assignment of the semiconductor chips 32 to the sub-areas 40. With the received set of measured variables, the semiconductor chips 32 are divided into the sub-areas 40 by projecting the measured variables into the sub-areas 40. Position data on the wafer 30 is assigned to the measured variables of the semiconductor chips 32. The measured variables of the semiconductor chips 32 are assigned x-coordinates and y-coordinates as position data on the wafer 30. The measured variables of the semiconductor chips 32 are projected into the sub-areas 40 using the position data. The measured variables are assigned to the sub-areas 40 by comparing the position data of the semiconductor chips 32 with the sub-area boundaries.

In at least one further method step 18, the set of measured variables is reduced. The received set of measured variables is reduced. The received set of measured variables is reduced by a selection of the measured variables of a subset of semiconductor chips 32, 34 of the respective sub-areas 40. A subset of semiconductor chips 32, 34 is selected in each sub-area 40. The subset of measured variables for the subset of semiconductor chips 32, 34 in the sub-areas 40 has completely available sets of measured variables. The measured variables of the semiconductor chips 32 that are reduced are removed from the set of measured variables. The reduced set of measured variables comprises approximately 10% of the measured variables compared to the received set of measured variables. In the sub-areas 40, approximately 10% of the semiconductor chips 32 located in the sub-areas 40 are selected.

In at least one embodiment of the method 10 according to the disclosure, the semiconductor chips 32, 34 of the respective sub-areas 40 whose measured variables are assigned to the reduced set of measured variables are determined at least partially at random. In each sub-area 40 on the wafer 30, the subset of semiconductor chips 32, 34 is determined randomly. In each sub-area 40 on the wafer 30, the measured variables of the semiconductor chips 32, 34 are determined randomly. The subset of the semiconductor chips 32, 34 is different with respect to a position of the semiconductor chips 32, 34 in each sub-area 40 on the wafer 30. A number or the proportion of the semiconductor chips 32, 34 in the respective sub-areas 40 on the at least one wafer 30 is at least approximately the same. Based on the position data of the projected measured quantities of the semiconductor chips 32 in the received set of measured quantities, the subset of semiconductor chips 32, 34 in the respective sub-areas 40 is randomly determined.

In a further embodiment of the method 10 according to the disclosure, the semiconductor chips 32, 34 of the respective sub-areas 40, whose measured variables are assigned to the reduced set of measured variables, are determined at least partially according to a predetermined pattern. A pattern is defined for the sub-areas 40 of the wafer 30, on the basis of which the subset of semiconductor chips 32, 34 is determined. As a predetermined pattern, a number and a position of the subset of semiconductor chips 32, 34 are determined for the reduced set of measured variables in the sub-areas 40. At least one semiconductor chip 32, 34 is determined as a predetermined pattern in each sub-area 40. In each sub-area 40, the measured variables of at least one semiconductor chip 32, 34 are determined as a predetermined pattern.

After reducing the set of measured variables for at least one sub-area 40, a query 20 is used to query whether further sub-areas 40 are still present on the wafer 30. If at least one further sub-area 40 is still present on the wafer 30, for which the set of measured variables has not been reduced, at least the method step 18 is repeated for the at least one further sub-area 40. If no further sub-areas 40 on the wafer 30 are detected during the query 20, at least one further method step 22 is executed.

In method step 22, the reduced set of measured variables is output. The reduced set of measured variables compared to the received set of measured variables is output. The output reduced set of measured variables comprises only the measured variables of subsets of the semiconductor chips 32, 34 of the respective sub-areas 40. The output set of measured variables comprises approximately 10% of the measured variables of the received set of measured variables.

FIG. 2 shows the wafer 30 with the semiconductor chips 32, 34 and a system 50 for providing the wafer test data in a schematic representation. The wafer 30 shown is representative of a plurality of wafers. The number of semiconductor chips 32 shown on the wafer 30 may vary as desired and is not limited to the number shown. The at least one wafer 30 is completely manufactured when the measured variables are measured. The semiconductor chips 32 on the wafer 30 are completely manufactured when the measured variables are measured. All layers of the wafer 30 are produced when the measured variables are measured. When measuring the measured variables, the semiconductor chips 32 are fully wired on the wafer 30.

The sub-areas 40 on the wafer 30 are defined in a grid shape. The sub-areas 40 have horizontal and vertical sub-area boundaries. The wafer 30 has nine sub-areas 40. A subset of semiconductor chips 32, 34 is defined in each of the sub-areas 40. The measured quantities of the subset of semiconductor chips 32, 34 for each sub-area 40 of the at least one wafer 30 form the reduced set of measured quantities.

The system 50 has a computing device. The computing device is configured to execute the method 10 for providing the wafer test data. The computing device has at least one processor. The computing device has a storage medium. The storage medium is a computer-readable storage medium. The computing device has input and output means. The computing device has an operating program, control routines, control routines and/or calculation routines. The storage medium of the rich device has a computer program with program code for carrying out the method 10 for providing the wafer test data. The computer program including program code comprises instructions which, when the program code is executed by a computer, cause the computer to execute at least the method 10 for providing the wafer test data. The processor is used to execute the method 10 for providing the wafer test data. The processor is used to execute the computer program with program code. The components of the computing device are arranged on a common circuit board. In an alternative embodiment according to the disclosure, the computing device is designed as a distributed, virtual computing device.

Measured variables of the semiconductor chips 32 are entered into the input means of the computing device. The method steps 12, 14, 16, 18, 22 and the query 20 are executed with the processor of the computing device. The set of measured variables of the semiconductor chips 32 is received by the processor of the computing device. The processor is used to define the sub-areas 40 on the at least one wafer 30. The set of measured variables of the semiconductor chips 32, 34 is output with the processor. The set of measured variables is output to the storage medium of the computing device. The set of measured variables is provided as the wafer test data on the storage medium of the computing device. The wafer test data is provided as a training data set via the output device.

Additionally or alternatively, the system 50 is provided for teaching the machine learning algorithm. The computing device is configured to execute the method for teaching the machine learning algorithm.

The computer program with program code comprises instructions which, when the program code is executed by a computer, cause the computer to execute at least the method for teaching the machine learning algorithm.

FIG. 3 shows a further exemplary embodiment of the disclosure. The following description and the drawing are essentially limited to the differences between the exemplary embodiments, wherein reference can also be made in principle to the drawing and/or the description of the exemplary embodiment in FIG. 2 with regard to components with the same designation, in particular with regard to components with the same reference symbols. To distinguish the exemplary embodiment in FIG. 3, the reference signs are followed by an apostrophe.

FIG. 3 shows a wafer 30′ with semiconductor chips 32′, 34′ and a system 50′ for providing wafer test data in a schematic representation. The wafer 30′ is divided into sub-areas 40′. The sub-areas 40′ are defined on the basis of the properties of the wafer 30′. One quality of the semiconductor chips 32′ is radially concentrically dependent on the wafer 30′. Circular sub-areas 40′ are defined on the wafer 30′ based on the properties of the wafer 30′. The sub-areas 40′ are concentric. Each sub-area 40′ has a uniform distance from the center of the wafer 30′. In a concentric outer sub-area 40′ of the wafer 30′, more semiconductor chips 32′ are determined as a subset of the semiconductor chips 32′, 34′ than in a concentric inner sub-area 40′ of the wafer 30′ due to quality. The measured quantities of the subset of semiconductor chips 32′, 34′ for each sub-area 40′ of the at least one wafer 30′ form the reduced set of measured quantities.

FIG. 4 shows a flowchart of another method 60 for providing wafer test data. In the further method 60, the number of measured semiconductor chips 32, 34 is reduced. The further method 60 is provided for providing wafer test data of at least one wafer 30 having a plurality of semiconductor chips 32. The further method 60 is for providing a training data set for a machine learning algorithm for anomaly detection. In at least one method step 62, sub-areas 40 are defined on the wafer 30. The sub-areas 40 each comprise a plurality of semiconductor chips 32 of the wafer. The sub-areas 40 are at least partially defined in accordance with method step 14. In at least one further method step 64, a subset of semiconductor chips 32, 34 is determined in the sub-areas 40 of the wafer 30. The subset of semiconductor chips 32, 34 in the sub-areas 40 is at least partially determined according to the method step 18. In at least one further method step 66, only the subset of the semiconductor chips 32, 34 in the respective sub-areas 40 is measured. After measuring the semiconductor chips 32, 34 in at least one sub-area 40, a query 68 is used to check whether a further sub-area 40 is present on the wafer 30. If there is another sub-area 40 on the wafer 30, the method step 66 is executed again. If no further sub-area 40 is present on the wafer 30, at least one further method step 70 is executed. In method step 70, a set of measured variables is output. The measured set of measured variables is at least partially output in accordance with method step 22.

What is claimed is:

1. A method for providing wafer test data of at least one wafer with semiconductor chips, for providing a training data set for a machine learning algorithm for anomaly detection, comprising:
receiving a set of measured variables from the semiconductor chips of the at least one wafer;
defining sub-areas on the at least one wafer, each of which comprises a plurality of semiconductor chips of the at least one wafer for which measured variables have been received, wherein the sub-areas are defined in a circular or grid-like manner; and
outputting a set of measured variables which is reduced in comparison with the received set of measured variables and which comprises only the measured variables of subsets of the semiconductor chips of the respective sub-areas, wherein the semiconductor chips of the respective sub-areas whose measured variables are assigned to the reduced set of measured variables are determined at least partially at random.

2. The method according to claim 1, wherein the semiconductor chips of the respective sub-areas whose measured variables are assigned to the reduced set of measured variables are determined at least partially according to a predetermined pattern.

3. The method according to claim 1, wherein the sub-areas are defined on the basis of properties of the at least one wafer and/or on the basis of photomask positions and/or exposure schemes from a manufacturing process of the at least one wafer.

4. The method according to claim 1, wherein a probability distribution for a presence of an anomaly on the at least one wafer is determined and the sub-areas on the at least one wafer are defined as a function of the determined probability distribution.

5. A method for providing wafer test data of at least one wafer having a plurality of semiconductor chips, for providing a training data set for a machine learning algorithm for anomaly detection, comprising:
defining sub-areas on the at least one wafer, each of which comprises a plurality of semiconductor chips of the at least one wafer;
measuring only a subset of the semiconductor chips in the respective sub-areas; and
outputting a set of measured variables.

6. A method for teaching a machine learning algorithm for anomaly detection with a training data set, provided with at least the method according to claim 1.

7. A system for providing wafer test data and/or for teaching a machine learning algorithm, comprising a computing device which is configured to execute at least the method according to claim 1.

8. A computer program with program code, comprising instructions which, when the program code is executed by a computer, cause the computer to execute at least the method according to claim 1.

9. A computer-readable storage medium on which the computer program according to claim 8 is stored.
